(19) United States
(12) Patent Application Publication
(10) Pub. No.: US 2025/0351379 A1
(43) Pub. Date: Nov. 13, 2025

(54) SEMICONDUCTOR DEVICE AND METHOD OF MANUFACTURING SEMICONDUCTOR DEVICE

(71) Applicant: SK hynix Inc., Icheon-si (KR)

(72) Inventor: Jeong Hoon BAE, Icheon-si (KR)

(21) Appl. No.: 19/019,036

(22) Filed: Jan. 13, 2025

(30) Foreign Application Priority Data
May 7, 2024 (KR) 10-2024-0060024

(51) Int. Cl. H10B 63/00

(52) U.S. Cl. CPC H10B 63/24

(57) ABSTRACT

A semiconductor device may include an insulating layer, support patterns positioned in the insulating layer, first conductive lines each extending in a first direction, second conductive lines each extending in a second direction that crosses the first direction, and memory cells positioned at crossing regions of the first conductive lines and the second conductive lines. A lower surface of each of the first conductive lines includes convex portions that protrude toward the support patterns.

### CROSS-REFERENCE TO RELATED APPLICATION

This application claims priority under 35 U.S.C. §119 to Korean Patent Application No. 10-2024-0060024 filed on May 7, 2024, which is incorporated herein by reference in its entirety.

### BACKGROUND

### 1. Technical Field

The present disclosure relates to an electronic device and a method of manufacturing the electronic device, and more particularly, to a semiconductor device and a method of manufacturing the semiconductor device.

### 2. Related Art

An integration degree of a semiconductor device is mainly determined by an area occupied by a unit memory cell. Recently, as improvement in an integration degree of a semiconductor device in which a memory cell is formed as a single layer on a substrate reaches a limit, a three-dimensional semiconductor device in which memory cells are stacked on a substrate is being proposed. In addition, various structures and manufacturing methods are being developed in order to improve operation reliability of the semiconductor device.

### SUMMARY

According to an embodiment of the present disclosure, a semiconductor device may include an insulating layer, support patterns positioned in the insulating layer, first conductive lines each extending in a first direction, wherein a lower surface of each of the first conductive lines includes convex portions that protrude toward the support patterns, second conductive lines each extending in a second direction that crosses the first direction, and memory cells positioned at crossing regions of the first conductive lines and the second conductive lines.

According to an embodiment of the present disclosure, a method of manufacturing a semiconductor device may include forming a first conductive layer, wherein an upper surface of the first conductive layer includes concave portions that are arranged in a first direction and a second direction crossing the first direction, forming a variable resistance layer over the first conductive layer, the variable resistance layer including convex portions that protrude toward the concave portions of the first conductive layer, forming variable resistance lines that include the convex portions and each extend in the first direction, by etching the variable resistance layer, forming first conductive lines that include the concave portions and each extend in the first direction, by etching the first conductive layer, forming second conductive lines that each extend in the second direction on the variable resistance lines, and forming variable resistance patterns that are positioned at crossing regions of the first conductive lines and the second conductive lines and include the convex portions, by etching the variable resistance lines.

According to an embodiment of the present disclosure, a method of manufacturing a semiconductor device may include forming an insulating layer, forming support patterns that are positioned in the insulating layer and each have an upper surface of which a level is lower than that of the insulating layer, forming a first conductive layer on the insulating layer and the support patterns, the first conductive layer including convex portions protruding toward the support patterns, and forming a variable resistance layer over the first conductive layer, the variable resistance layer including convex portions at positions corresponding to the convex portions of the first conductive layer.

### BRIEF DESCRIPTION OF THE DRAWINGS

FIGS. 1A, 1B, and 1C are diagrams illustrating a semiconductor device according to an embodiment of the present disclosure.

FIGS. 2A, 2B, 3A, 3B, 4A, 4B, 5A, 5B, 6A, 6B, 7A, 7B, 8A, 8B, and 8C are diagrams illustrating a method of manufacturing a semiconductor device according to an embodiment of the present disclosure.

### DETAILED DESCRIPTION

Embodiments of the present disclosure relate to a semiconductor device and a method of manufacturing the semiconductor device having a stable structure and an improved characteristic.

According to embodiments of the present disclosure, a semiconductor device having a stable structure and improved reliability may be provided.

Hereinafter, some embodiments of the present disclosure are described with reference to the accompanying drawings. As used herein, including in the claims, “or” as used in a list of items (e.g., a list of items prefaced by a phrase such as “at least one of . . . or” or “one or more of” or “one or both of”) indicates an inclusive list such that, for example, a list of at least one of A, B, or C indicates A or B or C or AB or AC or BC or ABC (i.e., A and B and C).

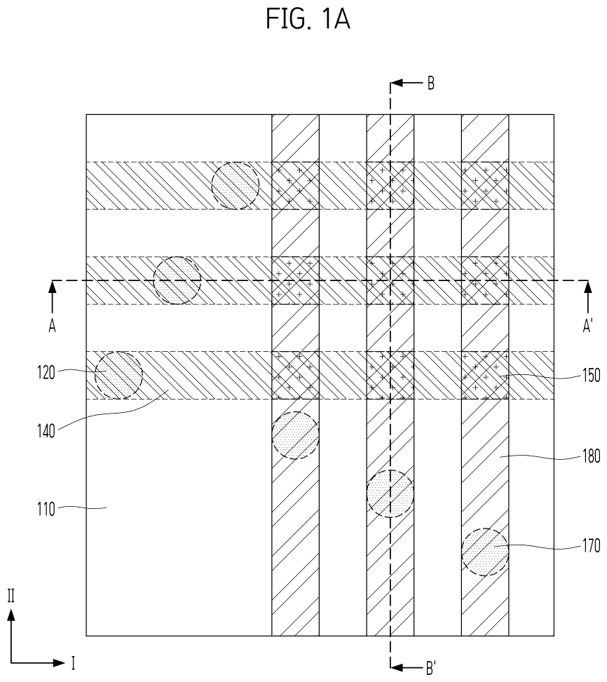

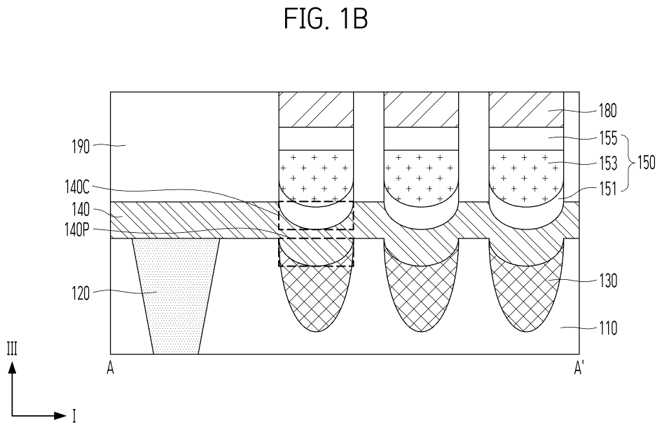

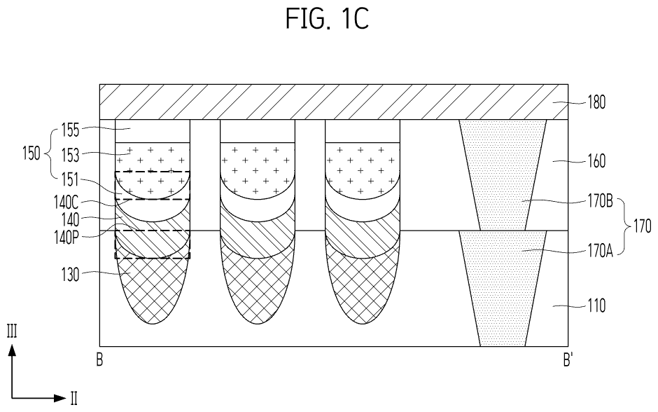

FIGS. 1A to 1C are diagrams illustrating a semiconductor device according to an embodiment of the present disclosure. FIG. 1A may be a plan view, FIG. 1B is a cross-sectional view taken along line A-A′ of FIG. 1A, and FIG. 1C is a cross-sectional view taken along line B-B′ of FIG. 1A.

Referring to FIGS. 1A to 1C, the semiconductor device may include at least one of an insulating layer 110, a support pattern 130, a first conductive line 140, a memory cell 150, or a second conductive line 180. The semiconductor device may further include at least one of a first contact via 120, a first gap fill pattern 160, a second contact via 170, or a second gap fill pattern 190.

The support patterns 130 may be positioned in the insulating layer 110. The support patterns 130 may be arranged at a position corresponding to the memory cells 150. For example, the support patterns 130 may be disposed to overlap the memory cells 150, respectively, when seen in a plan view. For example, the support patterns 130 may be arranged in a first direction I and a second direction II crossing the first direction I. A level of an upper surface of the support patterns 130 may be lower than a level of an upper surface of the insulating layer 110. For example, the upper surface of the support patterns 130 each may include a concave portion, and a level of a lower surface of the concave portion may be lower than the level of the upper surface of the insulating layer 110. Specifically, the concave portion of each of the support patterns 130 may be entirely lower than the upper surface of the insulating layer 110, except at boundaries where the support patterns 130 are contiguous to the upper surface of the insulating layer 110. As another example, the upper surface of each of the support patterns 130 may be substantially flat, and the level of the flat upper surface may be lower than the level of the upper surface of the insulating layer 110. Therefore, a step may occur between each of the support patterns 130 and the insulating layer 110.

As the step occurs between the support pattern 130 and the insulating layer 110, a thickness of a variable resistance layer may be adjusted in a process of manufacturing the semiconductor device. For example, a thickness of a portion to be etched of the variable resistance layer may be adjusted to be relatively thinner than a thickness of a remaining portion. In this case, damage to the variable resistance pattern 153 may be prevented or significantly reduced in the process of manufacturing the semiconductor device. Specifically, a variable resistance layer may include a first portion on an upper surface of a support pattern 130 and a second portion between adjacent support patterns 130 on the upper surface of the insulating layer 110. Since a level of an upper surface of the concave portion of the support pattern 130 is lower than the level of the upper surface of the insulating layer 110, the first portion of the variable resistance layer may have a first thickness greater than a second thickness of the second portion of the variable resistance layer. As a result, when the second portion of the variable resistance layer with the second thickness is etched to remain the first portion of the variable resistance layer as a variable resistance pattern 153, damage to the variable resistance pattern 153 may be prevented or significantly reduced compared to when a variable resistance layer has a substantially uniform thickness greater than the second thickness.

The support patterns 130 may include a material identical to that of the insulating layer 110, or may include a material different from that of the insulating layer 110. For example, the support patterns 130 and the insulating layer 110 may include oxide. The support patterns 130 may include a material having an etch rate higher than that of the insulating layer 110. For example, the support patterns 130 may include at least one of borophosphosilicate glass (BPSG), undoped silicate glass (USG), or high aspect ratio process (HARP) oxide. Here, the insulating layer 110 may include tetraethyl orthosilicate (TEOS).

The first conductive lines 140 may be positioned on the insulating layer 110 and the support patterns 130. The first conductive lines 140 may each extend in the first direction I. The first conductive lines 140 may be spaced apart from each other in the second direction II. The first conductive lines 140 may include convex portions 140P and concave portions 140C. The convex portions 140P may protrude toward the support patterns 130. For example, the convex portions 140P may protrude toward the support patterns 130 to fill spaces (e.g., steps) associated with level differences between the support patterns 130 and the insulating layer 110. Such a lower surface of each of the convex portions 140P may include a curved surface or may be substantially flat. The concave portions 140C may be positioned to correspond to the convex portions 140P, respectively. Specifically, the concave portions 140C may be positioned to overlap the convex portions 140P, respectively, when seen in a plan view. For example, the concave portions 140C may include an upper surface (e.g., a curved surface) or may be substantially flat. The first conductive lines 140 may be word lines or bit lines. The first conductive lines 140 may include a conductive material such as tungsten.

The second conductive lines 180 may cross the first conductive lines 140 and may be positioned on the first conductive lines 140. The second conductive lines 180 may each extend in the second direction II. The second conductive lines 180 may be spaced apart from each other in the first direction I. An upper surface and a lower surface of the second conductive lines 180 may be substantially flat. The second conductive lines 180 may be bit lines or word lines. The second conductive lines 180 may include a conductive material such as tungsten.

The memory cells 150 may be positioned between the first conductive lines 140 and the second conductive lines 180. For example, the memory cells 150 may be positioned in crossing regions of the first conductive lines 140 and the second conductive lines 180. The memory cells 150 may be arranged in the first direction I and the second direction II. The memory cell 150 may include at least one of a first electrode pattern 151, a variable resistance pattern 153, or a second electrode pattern 155. Here, the second electrode pattern 155 may be positioned on the first electrode pattern 151, and the variable resistance pattern 153 may be positioned between the first electrode pattern 151 and the second electrode pattern 155.

The memory cells 150 may fill spaces defined by the concave portions 140C of the first conductive lines 140. For example, the first electrode pattern 151 may fill a space defined by the concave portion 140C of the first conductive line 140. In some examples, the first electrode pattern 151 and/or a lower portion of the variable resistance pattern 153 may fill a space defined by the concave portion 140C of the first conductive line 140. An upper surface and a lower surface of the first electrode pattern 151 each may be a curved surface. For example, the upper surface of the first electrode pattern 151 may include a concave portion with a curved upper surface, and the lower surface may include a convex portion with a curved lower surface. The convex portion of the lower surface of the first electrode pattern 151 may fill a space defined by the concave portion 140C of the first conductive line 140. An upper surface of the variable resistance pattern 153 may be substantially flat and a lower surface of the variable resistance pattern 153 may be a curved surface. For example, the lower surface of the variable resistance pattern 153 may include a convex portion. The convex portion of the lower surface of the variable resistance pattern 153 may fill a space defined by the concave portion of the upper surface of the first electrode pattern 151. An upper surface and a lower surface of the second electrode pattern 155 may be substantially flat.

Due to a space (e.g., a step) associated with a level difference between each of the support patterns 130 and the insulating layer 110, the upper surface and the lower surface of the first conductive lines 140, the upper surface and the lower surface of the first electrode pattern 151, and the lower surface of the variable resistance pattern 153 may each be a curved surface. Meanwhile, by performing a planarization process in the process of manufacturing the semiconductor device, the upper surface of the variable resistance pattern 153, the upper surface and the lower surface of the second electrode pattern 155, and the upper surface and the lower surface of the second conductive line 180 may each be substantially flat. However, various embodiments of the present disclosure are not limited thereto, and when the variable resistance layer is formed sufficiently thick in the process of manufacturing the semiconductor device, the upper surface of the variable resistance pattern 153 may be substantially flat, and thus a separate planarization process may not be performed.

The first electrode pattern 151 may be a portion of the first conductive line 140 or may be electrically connected to the first conductive line 140. The second electrode pattern 155 may be a portion of the second conductive line 180 or may be electrically connected to the second conductive line 180. The first electrode pattern 151, or the second electrode pattern 155, or both may include a conductive material such as polysilicon or metal. For example, the first electrode pattern 151, or the second electrode pattern 155, or both may include polysilicon, tungsten (W), tungsten nitride (WNx), tungsten silicide (WSix), titanium (Ti), titanium nitride (TiNx), titanium silicon nitride (TiSiN), titanium aluminum nitride (TiAlN), tantalum (Ta), tantalum nitride (TaN), tantalum silicon nitride (TaSiN), tantalum aluminum nitride (TaAlN), carbon (C), silicon carbide (SiC), silicon carbon nitride (SiCN), copper (Cu), zinc (Zn), nickel (Ni), cobalt (Co), lead (Pd), platinum (Pt), molybdenum (Mo), ruthenium (Ru), and the like, and may include a combination thereof.

The variable resistance pattern 153 may maintain an amorphous state during a program operation and may not change to a crystalline state after the program operation. In other words, a phase of the variable resistance pattern 153 may not change after the program operation. The variable resistance pattern 153 may be used as both of a memory element and a selection element. The variable resistance pattern 153 may include a resistive material and may have a characteristic that reversibly changes between different resistance states according to an applied voltage or current. For example, the variable resistance pattern 153 may include a variable resistance material of which a resistance changes without a phase change, and may include a chalcogenide element. The variable resistance pattern 153 may include germanium (Ge), antimony (Sb), arsenic (As), silicon (Si), indium (In), tin (Sn), gallium (Ga), and the like, and may include a combination thereof.

The variable resistance pattern 153 may include a phase change material and may include chalcogenide. The variable resistance pattern 153 may include chalcogenide glass, chalcogenide alloy, and the like. The variable resistance pattern 153 may change phase according to the program operation. For example, the variable resistance pattern 153 may have a crystalline state of a low resistance by a set operation. In addition, the variable resistance pattern 153 may have an amorphous state of a high resistance by a reset operation. Therefore, data may be stored in the memory cell 150 by using a resistance difference according to the phase of the variable resistance pattern 153.

The variable resistance pattern 153 may include a transition metal oxide or may include a metal oxide such as a perovskite-based material. Therefore, as an electrical path is generated or extinct in the variable resistance pattern 153, data may be stored in the memory cell.

The variable resistance pattern 153 may have an MTJ structure and may include a magnetization pinned layer, a magnetization free layer, and a tunnel barrier layer interposed between the magnetization pinned layer and the magnetization free layer. For example, the magnetization pinned layer and the magnetization free layer may include a magnetic material, and the tunnel barrier layer may include an oxide such as magnesium (Mg), aluminum (Al), zinc (Zn), and titanium (Ti). Here, a magnetization direction of the magnetized free layer may be changed by a spin torque of electrons in an applied current. Therefore, data may be stored in the memory cell 150 according to a change of the magnetization direction of the magnetization free layer with respect to a magnetization direction of the magnetization pinned layer.

In addition, the variable resistance pattern 153 may have a metal-insulator-metal (MIM) structure including metal oxide. In this case, data may be stored in the memory cell 150 using a resistance change of the metal oxide that occurs when a short electric pulse is applied.

The memory cell 150 may further include at least one of a switching pattern (not shown) or a third electrode pattern (not shown). For example, the switching pattern may be positioned on the first electrode pattern 151, and the third electrode pattern may be positioned between the switching pattern and the variable resistance pattern 153. However, embodiments of the present disclosure are not limited thereto, and positions of the variable resistance pattern 153 and the switching pattern may be mutually changed.

The first electrode pattern 151, the switching pattern, and the third electrode pattern may configure a selection element. In addition, the third electrode pattern, the variable resistance pattern 153, and the second electrode pattern 155 may configure a memory element. In this case, the memory element and the selection element may share the third electrode pattern. The selection element may be a diode, a PNP diode, a transistor, a vertical transistor, a bipolar junction transistor (BJT), a metal insulator transition (MIT) element, a mixed ionic-electronic conduction (MIEC) element, an ovonic threshold switching (OTS) element, or the like. For example, the switching pattern, or the variable resistance pattern 153, or both may include a chalcogenide material. The first electrode pattern 151 may be a lower electrode, the third electrode pattern may be an intermediate electrode, and the second electrode pattern 155 may be an upper electrode.

The first gap fill pattern 160, or the second gap fill pattern 190, or both may be positioned on the insulating layer 110. The first gap fill pattern 160, or the second gap fill pattern 190, or both may be positioned between the memory cells 150. For example, the first gap fill pattern 160 may be positioned between memory cells 150 neighboring in the second direction II, and the second gap fill pattern 190 may be positioned between memory cells 150 neighboring in the first direction I. The first gap fill pattern 160, or the second gap fill pattern 190, or both may include an insulating material such as oxide.

The first contact vias 120 may be positioned in the insulating layer 110. For example, the first contact vias 120 may pass through the insulating layer 110. The first contact vias 120 may be connected to the first conductive lines 140. A level of an upper surface of the first contact via 120 may be substantially the same as the level of the upper surface of the insulating layer 110. However, embodiments of the disclosure are not limited thereto, and the level of the upper surface of the first contact via 120 may be lower than the level of the insulating layer 110. For example, the upper surface of the first contact via 120 may include a concave portion, and a level of a lower surface of the concave portion may be lower than the level of the upper surface of the insulating layer 110. As another example, the upper surface of the first contact vias 120 may be substantially flat, and the level of the flat upper surface of the first contact via 120 may be lower than the level of the upper surface of the insulating layer 110. The first contact vias 120 may each include a conductive material such as tungsten.

The second contact vias 170 may pass through the insulating layer 110. Each of the second contact vias 170 may include a first portion 170A and a second portion 170B on the first portion 170A. The first portion 170A may pass through the insulating layer 110, and the second portion 170B may pass through the first gap fill pattern 160. The second contact vias 170 may be connected to the second conductive lines 180. A level of an upper surface of the first portion 170A of the second contact via 170 may be substantially the same as the level of the upper surface of the insulating layer 110. However, embodiments of the disclosure are not limited thereto, and the level of the upper surface of the first portion 170A may be lower than the level of the upper surface of the insulating layer 110. This is because the first portion 170A may be formed when forming the first contact vias 120 in the process of manufacturing the semiconductor device. The second contact vias 170 may include a conductive material such as tungsten.

According to the structure described above, the level of the upper surface of the support patterns 130 may be lower than the level of the upper surface of the insulating layer 110. In this case, a space associated with such a level difference (e.g., a step) may occur between each of the support patterns 130 and the insulating layer 110. Therefore, damage to the variable resistance patterns 153 to be formed at a position corresponding to the support patterns 130 in the process of manufacturing the semiconductor device may be reduced.

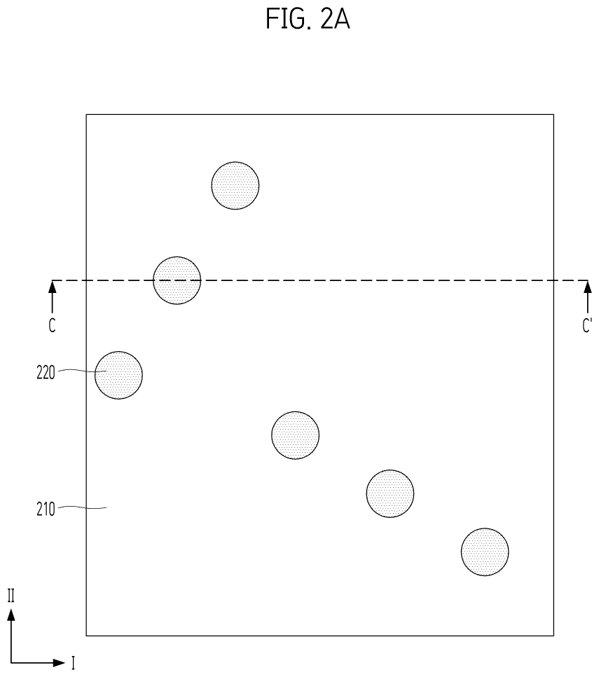

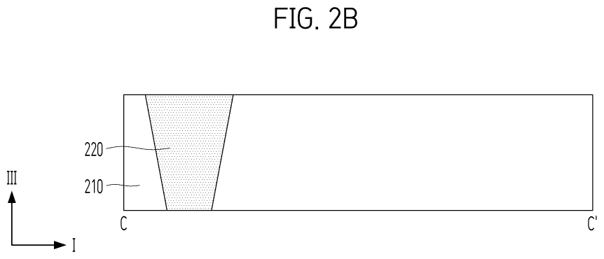

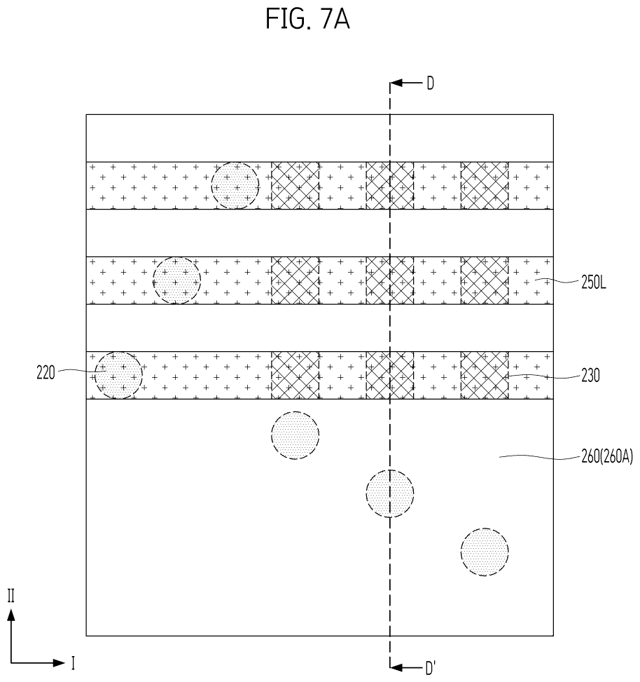

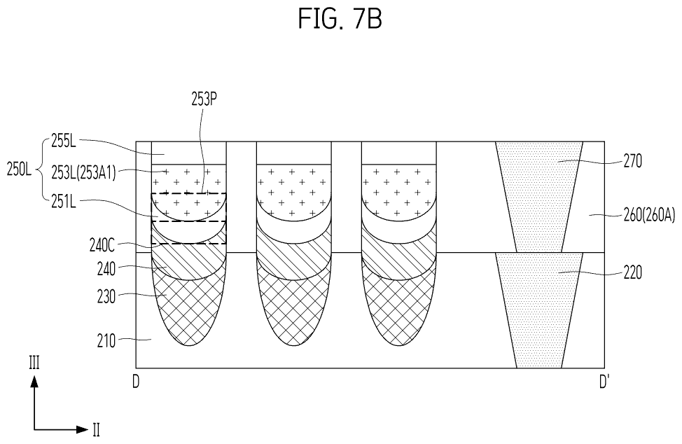

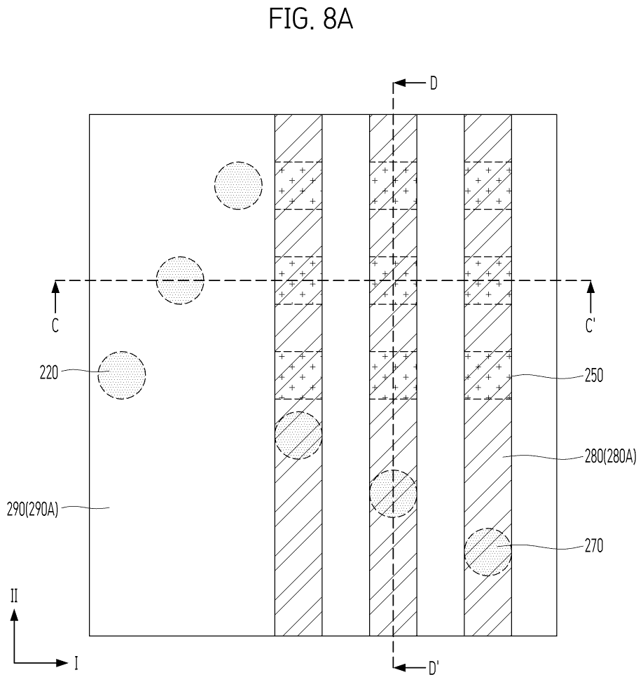

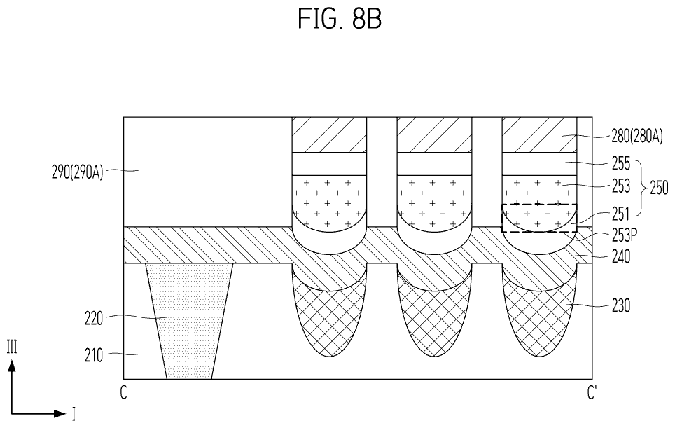

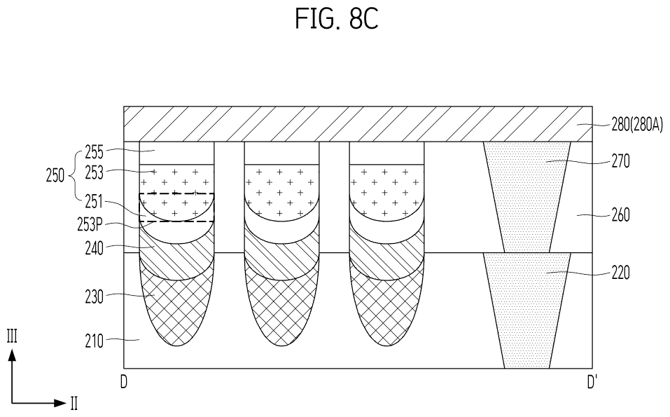

FIGS. 2A to 8C are diagrams illustrating a method of manufacturing a semiconductor device according to an embodiment of the present disclosure. FIGS. 2A, 3A, 4A, 5A, 6A, 7A, and 8A may be plan views, FIGS. 2B, 3B, 4B, 5B, 6B, and 8B are cross-sectional views taken along line C-C′ of FIGS. 2A, 3A, 4A, 5A, 6A, and 8A, respectively, and FIGS. 7B and 8C are cross-sectional views taken along line D-D′ of FIGS. 7A and 8A, respectively. Hereinafter, descriptions that overlap those described above may be omitted for the interest of brevity.

Referring to FIGS. 2A and 2B, an insulating layer 210 may be formed. Here, the insulating layer 210 may include oxide. For example, the insulating layer 210 may include TEOS.

Subsequently, first contact vias 220 may be formed in the insulating layer 210. The first contact vias 220 may be formed in regions where first conductive lines (not shown) or second conductive lines (not shown) are to be formed. Here, the first contact vias 220, which are formed in the regions where the second conductive lines are to be formed, each may be used as a portion (e.g., a first portion 170A in FIG. 1C) of the second contact vias (not shown). The first contact vias 220 may include a conductive material such as tungsten.

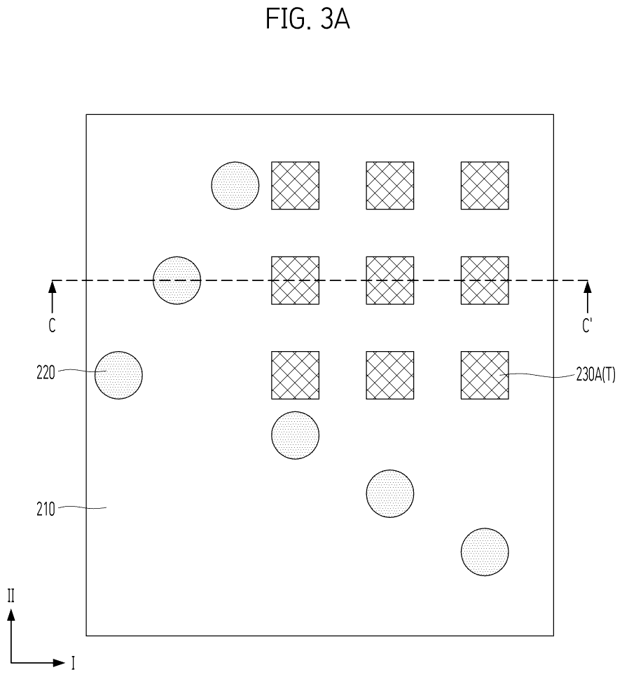

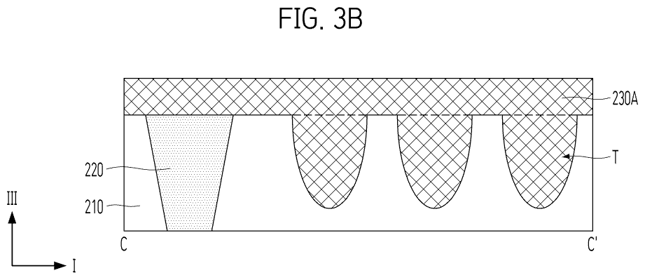

Referring to FIGS. 3A and 3B, trenches T may be formed in the insulating layer 210. The trenches T arranged in the first direction I and the second direction II crossing the first direction I may be formed in the insulating layer 210.

Subsequently, a support layer 230A may be formed to fill the trenches T. The support layer 230A in FIG. 3B is not shown in FIG. 3A for clearly illustrating structures underlying the support layer 230A. Here, the support layer 230A may include a material substantially identical to that of the insulating layer 210 or may include a material different from that of the insulating layer 210. For example, the support layer 230A may include oxide. The support layer 230A may include a material of which an etch rate is different from that of the insulating layer 210. For example, the support layer 230A may include a material having an etch rate higher than that of the insulating layer 210. The support layer 230A may include borophosphosilicate glass (BPSG), undoped silicate glass (USG), or high aspect ratio process (HARP) oxide.

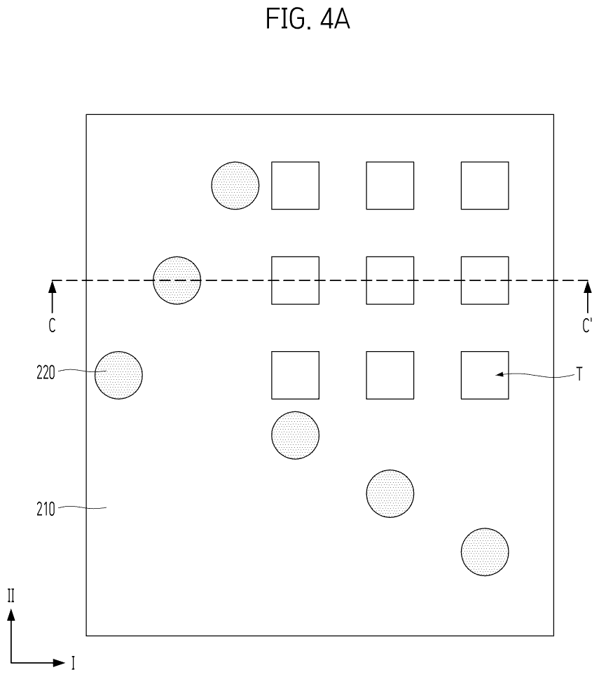

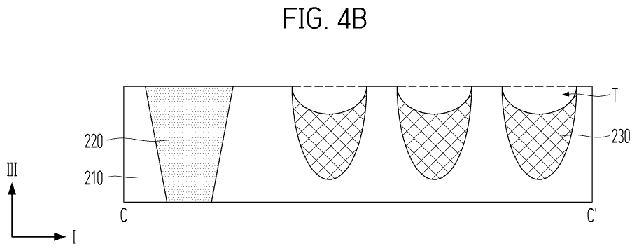

Referring to FIGS. 4A and 4B, support patterns 230 may be formed. For example, the support patterns 230 may be formed in the trenches T by planarizing the support layer 230A so that an upper surface of the insulating layer 210 is exposed. Here, because the support layer 230A includes the material of which the etch rate is higher than that of the insulating layer 210, the support layer 230A may be etched more than the insulating layer 210 in a process of planarizing the support layer 230A, and dishing may occur on an upper surface of the support pattern 230. In this case, a level of an upper surface of the support pattern 230 may be lower than that of the insulating layer 210. Therefore, a space (e.g., a step) may be formed resulting from a level difference between the support pattern 230 and the insulating layer 210.

In the embodiment of FIGS. 4A and 4B, the first contact vias 220 are not substantially etched in a planarization process, but embodiments of the present disclosure are not limited thereto. For example, a portion of an upper surface of the first contact via 220 may be etched in the planarization process, and dishing may be caused on the upper surface of the first contact via 220. In this case, a level of the upper surface of the first contact via 220 may be lower than that of an upper surface of the insulating layer 210.

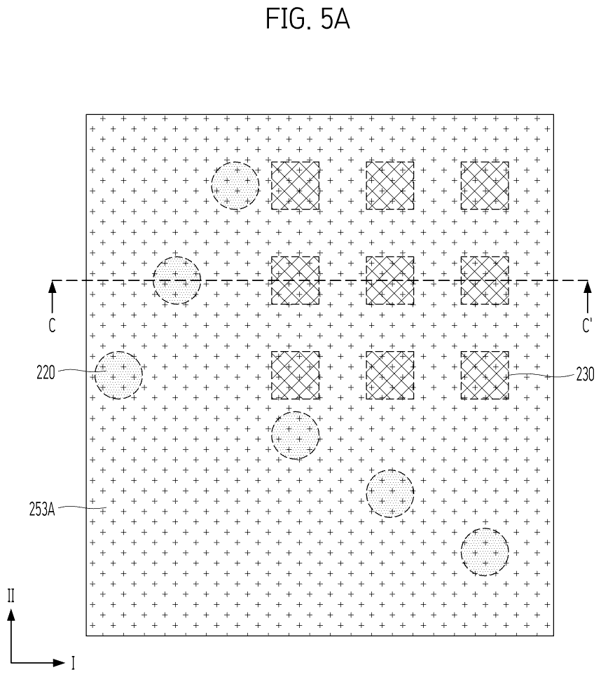

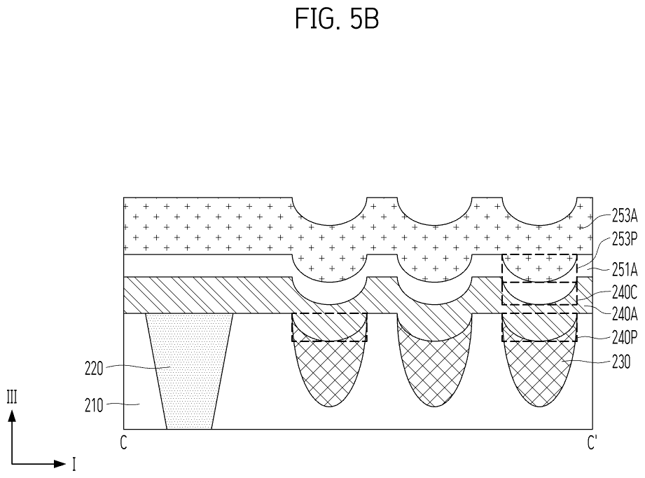

Referring to FIGS. 5A and 5B, a first conductive layer 240A may be formed on the insulating layer 210 and the support patterns 230. For example, the first conductive layer 240A may be formed conformally along a profile of the support patterns 230. In this case, the first conductive layer 240A may be formed to fill the spaces (e.g., steps) between the support patterns 230 and the insulating layer 210. For example, the first conductive layer 240A may include convex portions 240P protruding toward the support patterns 230 and each having a lower surface. The convex portions 240P may be formed to fill the spaces between the support patterns 230 and the insulating layer 210. For example, each of the convex portions 240P may be formed to fill a space defined by a concave portion of a corresponding one of the support patterns 230. In addition, the first conductive layer 240A may include concave portions 240C each having an upper surface. Here, the concave portions 240C may be positioned corresponding to the support patterns 230, respectively. Therefore, the concave portions 240C may be arranged in the first direction I and the second direction II. The first conductive layer 240A may include a conductive material such as tungsten.

Subsequently, a first electrode layer 251A may be formed along a profile of the first conductive layer 240A. In this case, the first electrode layer 251A may include convex portions that fill the concave portions 240C of the first conductive layer 240A and each have a lower surface (e.g., a lower curved surface), and may include concave portions positioned to respectively correspond to the support patterns 230 and each having an upper surface (e.g., an upper curved surface). The first electrode layer 251A may be formed of a conductive material including tungsten or carbon.

Subsequently, a variable resistance layer 253A may be formed on the first electrode layer 251A. For example, the variable resistance layer 253A may be formed along a profile of the first electrode layer 251A. In this case, the variable resistance layer 253A may include convex portions 253P protruding toward the concave portions 240C of the first conductive layer 240A and each having a lower surface (e.g., a lower curved surface), and may include concave portions positioned to respectively correspond to the support patterns 230 and each having an upper surface (e.g., an upper curved surface). In other words, the variable resistance layer 253A may include the convex portions 253P at positions corresponding to the convex portions 240P of the first conductive layer 240A. For example, the variable resistance layer 253A may include the convex portions 253P that fill the concave portions of the first electrode layer 251A, respectively. The variable resistance layer 253A may include a chalcogenide material.

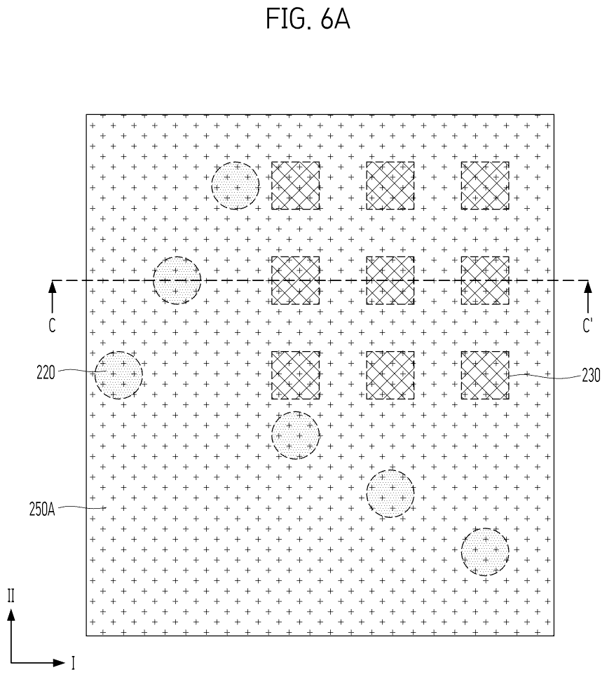

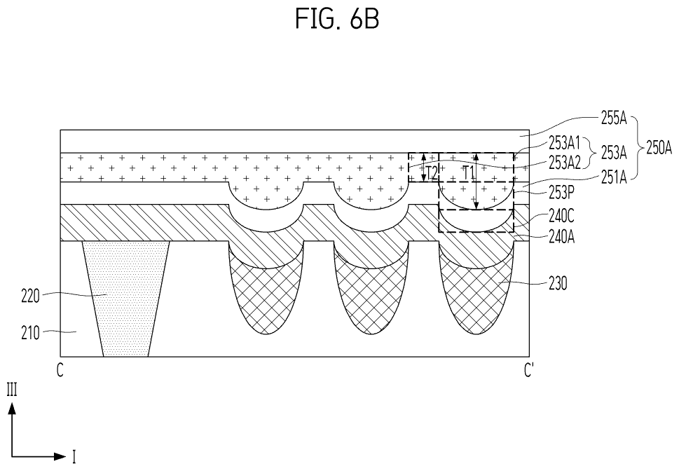

Referring to FIGS. 6A and 6B, the variable resistance layer 253A may be planarized. For example, the variable resistance layer 253A may be planarized so that an upper surface of the variable resistance layer 253A is substantially flat. In this case, the variable resistance layer 253A may include first portions 253A1 including convex portions 253P and second portions 253A2 that do not include the convex portions 253P. Here, the first portions 253A1 may have a first thickness T1, and the second portions 253A2 may have a second thickness T2 thinner than the first thickness T1. For example, the first portion 253A1 may have a first thickness T1 as a maximum thickness, and the second portion 253A2 may have a substantially uniform thickness T2.

In an embodiment, the second thickness T2 may be in a range of about 20% to 80% of the first thickness T1. When the second thickness T2 is greater than about 80% of the first thickness T1, risk of damaging a variable resistance pattern while etching the variable resistance layer 253A to form the variable resistance pattern may be excessively increased. When the second thickness T2 is smaller than about 20% of the first thickness T1, conformal deposition of the variable resistance layer 253A on the first electrode layer 251A may be difficult. However, the ranges of the first thickness T1 and the second thickness T2 are not limited to the above ranges. That is, the second thickness T2 must be less than the first thickness T1. The first portions 253A1 may be regions where memory cells (not shown) to be formed, and the second portions 253A2 each may be a region between the memory cells. The second portion 253A2 may be removed in a subsequent process.

For reference, although not shown in FIGS. 5A and 5B, when the variable resistance layer 253A is formed sufficiently thick on the first electrode layer 251A, concave portions may not occur in the upper surface of the variable resistance layer 253A. In other words, the upper surface of the variable resistance layer 253A may be substantially flat. In this case, a process of planarizing the variable resistance layer 253A may be omitted.

Subsequently, a second electrode layer 255A may be formed on the variable resistance layer 253A. Here, an upper surface and a lower surface of the second electrode layer 255A may be substantially flat. Therefore, a memory layer 250A including the first electrode layer 251A, the variable resistance layer 253A, and the second electrode layer 255A may be defined. The second electrode layer 255A may be formed of a conductive material including tungsten or carbon.

Referring to FIGS. 7A and 7B, second electrode lines 255L extending in the first direction I may be formed by etching the second electrode layer 255A. The second electrode lines 255L may be spaced apart from each other in the second direction II.

Subsequently, variable resistance lines 253L including convex portions 253P and extending in the first direction I may be formed by etching the variable resistance layer 253A. For example, the variable resistance lines 253L may be formed by etching the second portion 253A2 of the variable resistance layer 253A. In other words, the relatively thin second portion 253A2 may be removed, and the relatively thick first portions 253A1 may remain, to form the variable resistance lines 253L. Specifically, the second portions 253A2 of the variable resistance layer 253A that each extend in the first direction I and are arranged in the second direction II may be removed to form the variable resistance lines 253L. Here, because the second portion 253A2 is relatively thin, an etching time may be reduced. Therefore, according to embodiments of the present disclosure, as the etching time is reduced, damage to the first portions 253A1, which are a region where the memory cells to be formed, may be prevented or significantly reduced.

Subsequently, first electrode lines 251L extending in the first direction I may be formed by etching the first electrode layer 251A. The first electrode lines 251L may be spaced apart from each other in the second direction II. Therefore, memory lines 250L including the first electrode lines 251L, the variable resistance lines 253L, and the second electrode lines 255L may be defined.

Subsequently, first conductive lines 240 including concave portions 240C and extending in the first direction I may be formed by etching the first conductive layer 240A. Here, the first conductive lines 240 may be word lines or bit lines. The first contact vias 220 may be connected to the first conductive lines 240.

Subsequently, first gap fill patterns 260 may be formed. First, a first gap fill layer 260A may be formed to fill a space between the memory lines 250L. Subsequently, the first gap fill layer 260A may be planarized until upper surfaces of the memory lines 250L are exposed. In this case, the first gap fill layer 260A may be separated into the first gap fill patterns 260. The first gap fill patterns 260 may include an insulating material such as oxide.

Next, second contact vias 270 may be formed in the first gap fill pattern 260. The second contact vias 270 may be formed in a region where second conductive lines (not shown) are to be formed. For example, the second contact vias 270 may be formed to be connected to some of the first contact vias 220 formed in regions where the second conductive lines are to be formed. Here, such first contact vias 220 formed in the regions where the second conductive lines are to be formed may be electrically connected to the second contact vias 270. The second contact vias 270 may include a conductive material such as tungsten.

Referring to FIGS. 8A to 8C, second conductive lines 280 each extending in the second direction II may be formed. First, a second conductive layer 280A may be formed on the memory lines 250L. Subsequently, the second conductive lines 280 may be formed by etching the second conductive layer 280A. Here, the second conductive lines 280 may be bit lines or word lines. The second contact vias 270 may be connected to the second conductive lines 280.

Subsequently, memory cells 250 may be formed. For example, second electrode patterns 255, variable resistance patterns 253, and first electrode patterns 251 may be formed by sequentially etching the second electrode lines 255L, the variable resistance lines 253L, and the first electrode lines 251L. Therefore, the memory cells 250 including the second electrode patterns 255, the variable resistance patterns 253, and the first electrode patterns 251 may be formed. Here, the relatively thin second portions 253A2 of the variable resistance lines 253L may be removed by etching, and the first portions 253A1 where the memory cells 250 are to be formed may remain. Here, the remaining first portions 253A1 may configure the variable resistance patterns 253 of the memory cells 250. The variable resistance patterns 253 may include convex portions 253P.

Subsequently, second gap fill patterns 290 may be formed. First, a second gap fill layer 290A may be formed to fill a space between memory cells 250 neighboring in the first direction I. Subsequently, the second gap fill layer 290A may be planarized until upper surfaces of the memory cells 250 are exposed. In this case, the second gap fill layer 290A may be separated into the second gap fill patterns 290. The second gap fill patterns 290 may include an insulating material such as oxide.

According to the manufacturing method described above, the support patterns 230 of which the level of the upper surface is lower than that of the insulating layer 210 may be formed. In this case, a space associated with the level difference (e.g., a step) may occur between the insulating layer 210 and each of the support patterns 230.

The first conductive layer 240A may be formed to fill the spaces defined by the insulating layer 210 and the support patterns 230. The memory layer 250A including the variable resistance layer 253A may be formed on the first conductive layer 240A. Therefore, the variable resistance layer 253A may include the relatively thick first portions 253A1 corresponding to the supporting patterns 230 and the relatively thin second portions 253A2. Here, because each of the second portions 253A2 is relatively thin, an etching time to remove the second portions 253A2 to form the variable patterns 253 may be significantly reduced. Therefore, according to the present disclosure, as the etching time is reduced, damage to the first portions 253A1, which are the region where the memory cells are to be formed, may be prevented or significantly reduced.

Although some embodiments according to the technical spirit of the present disclosure have been described with reference to the accompanying drawings, various embodiments of the present disclosure are not limited to the above-described embodiments. Various forms of substitution, modification, and change of the embodiments may be possible by those skilled in the art to which the present disclosure belongs in light of teachings of the present disclosure, and may belong to the scope of the present disclosure.

What is claimed is:

1. A semiconductor device comprising:
an insulating layer;
support patterns positioned in the insulating layer;
first conductive lines each extending in a first direction, wherein a lower surface of each of the first conductive lines includes convex portions that protrude toward the support patterns;
second conductive lines each extending in a second direction that crosses the first direction; and
memory cells positioned at crossing regions of the first conductive lines and the second conductive lines.

2. The semiconductor device of claim 1, wherein an upper surface of each of the first conductive lines include concave portions positioned to correspond to the convex portions.

3. The semiconductor device of claim 2, wherein the memory cells fill spaces defined by the concave portions.

4. The semiconductor device of claim 1, wherein the support patterns are arranged in the first direction and the second direction.

5. The semiconductor device of claim 1, wherein a level of an upper surface of each of the support patterns is lower than a level of an upper surface of the insulating layer.

6. The semiconductor device of claim 1, wherein each of the memory cells includes a first electrode pattern, a second electrode pattern positioned on the first electrode pattern, and a variable resistance pattern positioned between the first electrode pattern and the second electrode pattern, and
wherein an upper surface the variable resistance pattern is substantially flat and a lower surface of the variable resistance pattern includes a curved surface.

7. The semiconductor device of claim 6, wherein the variable resistance pattern includes a phase change material.

8. The semiconductor device of claim 6, wherein an upper surface and a lower surface of the first electrode pattern each include a curved surface.

9. The semiconductor device of claim 6, wherein an upper surface and a lower surface of the second electrode pattern each are substantially flat.

10. The semiconductor device of claim 1, wherein an upper surface and a lower surface of each of the second conductive lines are substantially flat.

11. The semiconductor device of claim 1, wherein the support patterns each include a material of which an etch rate is different from that of the insulating layer.

12. The semiconductor device of claim 11, wherein the support patterns each include a material having an etch rate higher than that of the insulating layer.

13. The semiconductor device of claim 12, wherein the support patterns each include at least one of borophosphosilicate glass (BPSG), undoped silicate glass (USG), or high aspect ratio process (HARP) oxide.

14. A method of manufacturing a semiconductor device, the method comprising:
forming a first conductive layer, wherein an upper surface of the first conductive layer includes concave portions that are arranged in a first direction and a second direction crossing the first direction;
forming a variable resistance layer over the first conductive layer, the variable resistance layer including convex portions that protrude toward the concave portions of the first conductive layer;
forming variable resistance lines that include the convex portions and each extend in the first direction, by etching the variable resistance layer;
forming first conductive lines that include the concave portions and each extend in the first direction, by etching the first conductive layer;
forming second conductive lines that each extend in the second direction on the variable resistance lines; and
forming variable resistance patterns that are positioned at crossing regions of the first conductive lines and the second conductive lines and include the convex portions, by etching the variable resistance lines.

15. The method of claim 14, further comprising:
forming an insulating layer before forming the first conductive layer; and
forming support patterns that are positioned in the insulating layer and each have an upper surface of which a level is lower than that of the insulating layer.

16. The method of claim 15, wherein forming the support patterns comprises:
forming trenches that are arranged in the first direction and the second direction in the insulating layer;
forming a support layer including a material of which an etch rate is different from that of the insulating layer to fill the trenches; and
forming the support patterns in the trenches by planarizing the support layer so that an upper surface of the insulating layer is exposed.

17. The method of claim 15, wherein the support patterns each include a material having an etch rate higher than that of the insulating layer.

18. The method of claim 17, wherein the support patterns each include at least one of borophosphosilicate glass (BPSG), undoped silicate glass (USG), or high aspect ratio process (HARP) oxide.

19. The method of claim 18, wherein the insulating layer includes tetraethyl orthosilicate (TEOS).

20. The method of claim 15, wherein the concave portions of the first conductive layer are positioned to correspond to the support patterns.

21. The method of claim 15, wherein a lower surface of the first conductive layer further includes convex portions that protrude toward the support patterns.

22. The method of claim 14, wherein the variable resistance layer includes first portions including the convex portions and second portions positioned between the first portions, and
wherein each of the first portions has a first thickness, and each of the second portions has a second thickness thinner than the first thickness.

23. The method of claim 22, wherein the variable resistance lines are formed by etching the second portions.

24. The method of claim 14, further comprising:
forming a first electrode layer along a profile of the first conductive layer;
forming the variable resistance layer on the first electrode layer;
planarizing the variable resistance layer; and
forming a second electrode layer on the variable resistance layer to form a memory layer including the first electrode layer, the variable resistance layer, and the second electrode layer.

25. The method of claim 24, further comprising:
forming memory lines including second electrode lines, the variable resistance lines, and first electrode lines by etching the second electrode layer, the variable resistance layer, and the first electrode layer.

26. The method of claim 25, further comprising:
forming a memory cell including second electrode patterns, the variable resistance patterns, and first electrode patterns by etching the second electrode lines, the variable resistance lines, and the first electrode lines.

27. A method of manufacturing a semiconductor device, the method comprising:
forming an insulating layer;
forming support patterns that are positioned in the insulating layer and each have an upper surface of which a level is lower than that of the insulating layer;
forming a first conductive layer on the insulating layer and the support patterns, the first conductive layer including convex portions protruding toward the support patterns; and
forming a variable resistance layer over the first conductive layer, the variable resistance layer including convex portions at positions corresponding to the convex portions of the first conductive layer.

28. The method of claim 27, wherein forming the support patterns comprises:
forming trenches that are arranged in a first direction and a second direction crossing the first direction in the insulating layer;
forming a support layer including a material of which an etch rate is different from that of the insulating layer to fill the trenches; and
forming the support patterns in the trenches by planarizing the support layer so that an upper surface of the insulating layer is exposed.

29. The method of claim 27, wherein the support patterns each include a material having an etch rate higher than that of the insulating layer.

30. The method of claim 27, wherein the support patterns include at least one of borophosphosilicate glass (BPSG), undoped silicate glass (USG), or high aspect ratio process (HARP) oxide, and the insulating layer includes tetraethyl orthosilicate (TEOS).
